(19) United States
(12) Patent Application Publication
(10) Pub. No.: US 2011/0209755 A1
(43) Pub. Date: Sep. 1, 2011

(54) LIQUID CRYSTAL POLYMER BARRIER FILMS FOR OPTOELECTRONICS

(75) Inventors: Michael A. Zimmerman, North Andover, MA (US); Avin V. Dhoble, Waltham, MA (US); Frank J. Csillag, Hopkinton, MA (US)

(73) Assignee: SAINT-GOBAIN PERFORMANCE PLASTICS CORPORATION, Aurora, OH (US)

(21) Appl. No.: 12/979,624

(22) Filed: Dec. 28, 2010

Related U.S. Application Data
(60) Provisional application No. 61/290,795, filed on Dec. 29, 2009.

(51) Int. Cl. H01L 31/0232; H01L 31/18

(52) U.S. Cl. 136/257; 156/244.11

(57) ABSTRACT

An optoelectronic structure can include a liquid crystal polymer layer and an optoelectronic device adjacent to a first surface of the liquid crystal polymer layer. The liquid crystal polymer layer can include the first surface and a second surface opposite the first surface. In an embodiment, the liquid crystal polymer layer can further include a liquid crystal polymer at least partially exposed to a gas at the second surface. In another embodiment, the liquid crystal polymer may be a thermotropic liquid crystal polymer. In still another embodiment, the polymer layer can include an additive to reduce migration of a gas through the polymer layer. Methods of forming such optoelectronic structures can include melt-processing techniques.

### CROSS-REFERENCE TO RELATED APPLICATION(S)

The present application claims priority from U.S. Provisional Patent Application No. 61/290,795, filed Dec. 29, 2009, entitled “LIQUID CRYSTAL POLYMER BARRIER FILMS FOR OPTOELECTRONICS,” naming inventors Michael Zimmerman, Avin V. Dhoble and Frank J. Csillag, which application is incorporated by reference herein in its entirety.

### FIELD OF THE DISCLOSURE

The present disclosure generally relates to photovoltaic cells, and more particularly relates to liquid crystal polymer barrier films for optoelectronics.

### BACKGROUND

In recent years, increase in awareness of environmental problems has been spreading on a worldwide scale. Among others, concern is deep over the global warming phenomenon due to emission of CO₂, and desires for clean energy source have become stronger and stronger. At present, photovoltaic cells are considered to be a potential clean energy source because of their safety and easiness to handle.

Photovoltaic cells are often electrically connected and encapsulated as a photovoltaic module. Photovoltaic modules often have a sheet of glass on the front side to face the sun and allow light to pass while protecting semiconductor devices from environmental conditions (rain, hail, etc.). Additionally, the photovoltaic modules are protected from the environmental conditions on the back surface by a back sheet. As such, there is a need for continued improvement for photovoltaic cells.

### BRIEF DESCRIPTION OF THE DRAWINGS

The present disclosure may be better understood, and its numerous features and advantages made apparent to those skilled in the art by referencing the accompanying drawings.

FIG. 1 is a cross-section illustrating an exemplary optoelectronic structure.

FIG. 2 is a cross-section illustrating another exemplary optoelectronic structure.

The use of the same reference symbols in different drawings indicates similar or identical items.

### DETAILED DESCRIPTION

Numerous innovative teachings of the present disclosure will be described with particular reference to exemplary embodiments. However, it should be understood that this class of embodiments provides only a few examples of the many advantageous uses of the innovative teachings herein. In general, statements made in the present disclosure do not necessarily limit any of the various claimed articles, systems, or methods. Moreover, some statements may apply to some inventive features but not to others.

In an exemplary embodiment, an optoelectronic structure can include a liquid crystal polymer (LCP) layer, and an optoelectronic device adjacent to the LCP layer. The optoelectronic device can be a device for converting light to electricity, such as a photovoltaic cell. Alternatively, the optoelectronic component can be a device for converting electricity to light, such as a light emitting diode (LED), such as an organic light emitting diode (OLED), or the like. The optoelectronic structure can include the optoelectronic device and other optoelectronic devices that may be substantially identical to or different from each other. For example, the optoelectronic structure can be in the form of a solar panel, a display, or the like.

In the embodiments described herein, the term “front side” refers to the side of the optoelectronic device that receives the greater proportion of direct sunlight or emits a greater portion of light as seen by a user of the optoelectronic device. In embodiments, the front side is the active side of a photovoltaic device that converts sunlight to electricity. However, in some embodiments, the photovoltaic device can be constructed such that both sides of the device are active. For example, the front side can convert direct sunlight to electricity, while the back side can convert reflected sunlight to electricity. In other examples, the front side can receive direct sunlight at one point during the day and the back side at another point during the day. The embodiments described herein can include such photovoltaic constructions or other similar photovoltaic constructions. In a particular embodiment, the LCP layer can be on the back side of the photovoltaic cell, the front side of the photovoltaic cell, or any combination thereof.

As used herein, optoelectronic structure refers to one or more optoelectronic devices packaged within one or more protective layers. Additionally, a cell refers to a single device or a collection of devices. For example, an LED cell can correspond to a pixel of a LED display with each cell including three LED devices (a red-emitting LED, a green-emitting LED, and a blue-emitting LED).

The term “layer” refer to a single sheet (film or foil) or a combination of sheets (films or foils) collectively that perform a particular function. For example, an LCP layer can include one or more LCP films arranged to provide a barrier from moisture and the like. Further, the LCP layer may include additional films or foils to enhance the barrier properties of the LCP layer.

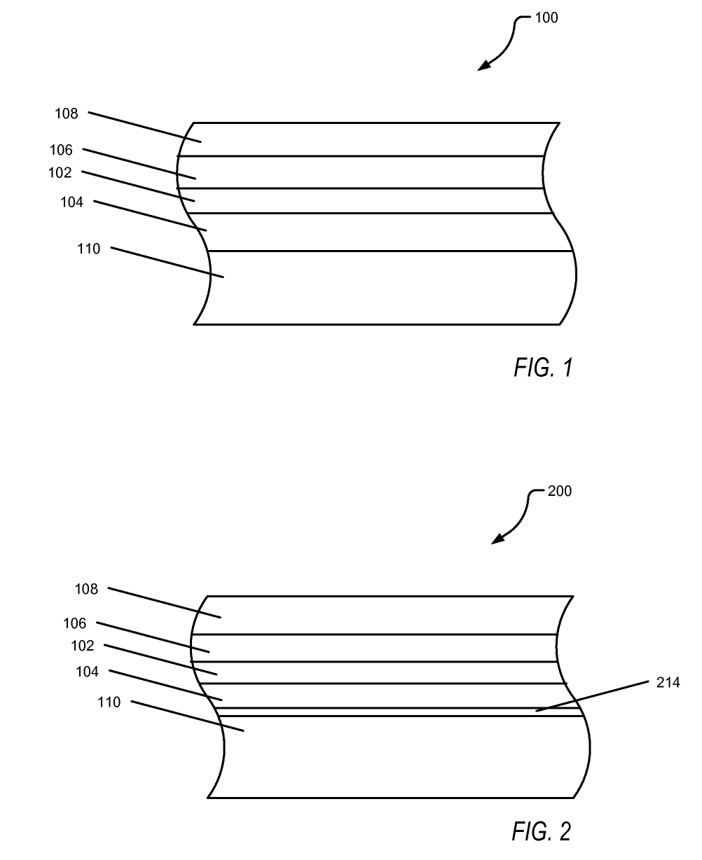

FIG. 1 illustrates an exemplary optoelectronic structure, generally designated 100. Optoelectronic structure 100 can include an optoelectronic device 102. In a particular embodiment, optoelectronic device 102 can include a photovoltaic cell. The photovoltaic cell can include a crystalline silicon photovoltaic device or a thin film photovoltaic device, such as a CdTe photovoltaic device, a Copper Indium Gallium Selenide (CIGS) photovoltaic device, an amorphous silicon photovoltaic device, a microcrystalline silicon photovoltaic device, a dye sensitized photovoltaic device, an organic photovoltaic device, or other suitable photovoltaic device. Optoelectronic device 102 can be encapsulated between polymer layer 104 and polymer layer 106 to protect the optoelectronic device 102 from physical shock, such as impacts.

In an embodiment, polymer layers 104 and 106 can include an encapsulant. Encapsulants are materials that help protect the photovoltaic device. Such materials include, for example a natural or synthetic polymer including a polyethylene, such as a linear low density polyethylene (LLDPE), a low density polyethylene, a high density polyethylene, and the like, a polypropylene, a nylon or a polyamide, an ethylene propylene diene monomer (EPDM), a polyester, a polycarbonate, an ethylene-propylene elastomer copolymer, a copolymer of ethylene or propylene with acrylic or methacrylic acid, an acrylate, a methacrylate, a ethylene-propylene copolymer, a poly alpha olefin melt adhesives such as, for example, ethylene vinyl acetate (EVA), ethylene butyl acrylate (EBA), ethylene methyl acrylate (EMA), and the like, an ionomer (an acid functionalized polyolefin generally neutralized as a metal salt), an acid functionalized polyolefins, a polyurethane such as thermoplastic polyurethane (TPU), an olefin elastomer, an olefinic block copolymer, a thermoplastic silicone, a polyvinyl butyral, a fluoropolymer, such as a terpolymer of tetrafluoroethylene, hexafluoropropylene, and vinylidene fluoride, or any combination thereof. Polymer layer 104 and polymer layer 106 can include substantially the same encapsulant. Alternatively, a different encapsulant can be used for each of polymer layers 104 and 106.

In another embodiment, polymer layer 104 or 106 can include a dielectric material. The dielectric material can include a polyethylene terephthalate (PET), a polycarbonate, or any combination thereof.

In an embodiment, polymer layers 104 and 106 can include one or more additives, such as a pigment, an ultraviolet (UV) stabilizer, an antioxidant, or any combination thereof. An exemplary pigment can include carbon black or titanium dioxide. Preferably, polymer layer 106 can be substantially transparent to the wavelengths of light received by the photovoltaic cell to produce electricity. As such, polymer layer 106 may be substantially free of pigments or other additives that would substantially reduce the transparency of layer 106.

In an exemplary embodiment, polymer layers 104 and 106 can have a thickness of at least about 12 microns (about 0.5 mils) and not greater than about 750 microns (about 30 mils). Additionally, the total thickness of polymer layer 104 and polymer layer 110 may be at least about 50 microns (about 2 mils), such as at least about 250 microns (about 10 mils), even at least about 1250 microns (about 50 mils).

Additionally, optoelectronic structure 100 may include a protective layer 108 overlying polymer layer 106. Protective Layer 108 can include glass, a liquid crystal polymer, or other suitable protective layers. Protective Layer 108 can provide a barrier between the environment and the optoelectronic device 102. Particularly, protective layer 108 can provide a diffusion barrier to substantially reduce diffusion of a gas to optoelectronic device 102. The gas may include a hydrogen-containing or an oxygen-containing gas, such as water vapor, diatomic oxygen, nitrogen oxides, carbon oxides, sulfur oxides, and the like. The hydrogen-containing or oxygen-containing gas can accelerate corrosion or degradation of optoelectronic device 102 or electrical connections to optoelectronic device 102, reducing the working life of optoelectronic structure 100.

In an embodiment, optoelectronic structure 100 can include an LCP layer 110 underlying polymer layer 104. As with layer 108, LCP layer 110 can provide a diffusion barrier to substantially reduce gases reaching the lower surface of the optoelectronic device 102. LCP layer 110 can include an LCP film including an LCP. As used herein, an LCP is a partially oriented aromatic polyester capable of forming highly oriented regions while in the liquid phase. In an embodiment, the partially oriented aromatic polyester can include a hydrobenzoic acid (HBA). Further, the LCP can exhibit optical anisotropy. The LCP film can include a thermotropic LCP or a lyotropic LCP. A thermotropic LCP can exhibit a phase transition into the liquid crystal phase as temperature is changed and is particularly advantageous when the LCP film is formed from a melted or molten LCP. A lyotropic LCP can exhibit phase transitions as a function of concentration of the LCP molecules in a solvent, and can be used when the LCP film is formed from a solvent-based process, rather than from a melted or molten LCP.

In a further embodiment, LCP layer 110 can include one or more fillers, such as a carbon filler, including graphite, carbon black, carbon nanotubes, and the like, a glass fiber, a mineral, a nano-particle, or any combination thereof. Additionally, LCP layer 110 can have a thickness of at least about 2.5 microns (about 0.1 mils), such as at least about 5 microns (about 0.2 mils), such as at least about 12.5 microns (about 0.5 mils), such as at least about 25 microns (about 1 mils), even at least about 50 microns (about 2 mils). In an embodiment, the LCP layer 110 may be not greater than about 250 microns (about 10 mils).

In an embodiment, LCP layer 110 can be a biaxially oriented LCP layer. A biaxially oriented LCP layer can have three distinct optical axes, rather than a single preferred axis around which the system is rotationally symmetric. A biaxially oriented layer or film can be generally isotropic along two orthogonal directions within the plane of the film. As such, the biaxially oriented LCP layer can have substantially the same physical properties in orthogonal directions within the plane. For example, the physical properties may not vary by greater than about 20%. In another embodiment, the physical properties may vary by not greater than about 10%. Advantageously, the biaxially oriented film has a low diffusion rate across the thickness direction due to the alignment of the long polymer chains transverse to the thickness of the layer.

Additionally, materials can be added to LCP layer 110 to further enhance the barrier properties of LCP layer 110. For example, LCP layer 110 can include a desiccant, such as an oxide, a chloride, a boric anhydride, a sulfate, or a hydroxide, another suitable desiccant, or any combination thereof. In a particular embodiment, the desiccant can include a chloride, a boric anhydride, a sulfate, or a hydroxide. The desiccant can be in the form of particulate material dispersed within the LCP layer 110 or a desiccant containing film can be placed adjacent to or between LCP films within LCP layer 110. In an alternate embodiment, the desiccant can be dispersed within a polymer layer adjacent to LCP layer 110, such as within polymer layer 104.

In yet another embodiment, LCP layer 110 can include a metal-containing sheet adjacent to the LCP film. The metal-containing sheet can include a metal foil or a metallized polymer film.

In a particular embodiment, LCP layer 110 can include a plurality of metal-containing sheets. The plurality of metal-containing sheets may be interspersed between a plurality of LCP films, such that there is an LCP film between each pair of adjacent metal-containing sheets. Alternatively, more than one metal-containing sheets may be disposed between adjacent LCP films (that is, no LCP film is between a pair of adjacent metal-containing sheets). Use of plurality of metal-containing sheets can provide increased resistance to gas diffusion. Specifically, a single metal-containing sheet may include a passageway that allows for gas diffusion through the metal-containing sheet. For example, the passageways can include imperfections, such as holes or tears, in the metal-containing sheets. A plurality of metal-containing sheets can provide a tortuous path through unaligned passageways in adjacent metal-containing sheets, slowing the rate of diffusion.

In an embodiment, optoelectronic structure 100 can be a photovoltaic structure. Optoelectronic device 102 can be a photovoltaic cell. Polymer layers 104 and 106 can include an encapsulant. Protective layer 108 can be a glass, an LCP layer, or any combination thereof. In a particular embodiment, protective layer 108 can be an LCP layer substantially similar to LCP layer 110.

In an embodiment shown in FIG. 2, optoelectronic structure 200 can include a tie layer 214. For example, tie layer 214 can be between LCP layer 110 and polymer layer 104. Tie layer 214 can be used to substantially prevent delamination of adjacent layers. Tie layer 214 can include a malic anhydride copolymer, an ethylene methyl acrylate copolymer (EMAC), an ethylene butyl acrylate copolymer (EBAC), a polyolefin melt adhesive, a modified polyolefin, an acrylic ethylene alkyl acrylate, another suitable tie material, or any combination thereof. The particular composition of each of tie layer 214 can depend on the composition of the adjacent layers. In a particular embodiment, an additional tie layer can be used between polymer layer 106 and protective layer 108 when protective layer 108 is an LCP layer.

In an embodiment, the LCP layer can be formed using a melt processing technique. The LCP can be heated to a temperature above the melt temperature of the LCP. In an embodiment, the LCP can be heated to at least about 20° C. above the melt temperature. Generally, the LCP may be heated to a temperature of not greater than about 30° C. above the melt temperature, and the residence time at temperatures above the melt temperature can be limited to minimize degradation of the LCP. In an embodiment, the LCP can be heated to a temperature of at least about 290° C. In another embodiment, the LCP may be heated to a temperature of not greater than 400° C. The heated LCP can be formed into a melt-processed film, such as a by extrusion, blowing, or melt casting. In another embodiment, the LCP containing polymer film can be formed using a solvent based process, such as by dissolving the LCP in a solvent and spreading the solvent into a layer, such as by spin casting, dip coating, or other suitable technique. The layer can be dried to remove the solvent to produce an LCP containing film. In yet another embodiment, the LCP layer can be formed by paste extrusion.

In another embodiment, the LCP layer can be formed at least partially by lamination. Lamination is particularly suitable when sheets of non-thermoplastic materials, such as metal foils, or desiccant sheets, are incorporated into the optoelectronic structure. For example, when forming a barrier structure including one or more metal foils interspersed with one or more LCP films, laminating can be used to form the barrier structure. Further, lamination may be used when the LCP layer includes a polymer film not amenable to the melt processing conditions required for the LCP. Specifically, a barrier laminate may be formed with a plurality of alternating metal foil and LCP films.

In a further embodiment, the LCP layer can be joined to an optoelectronic device. For example, the optoelectronic device, such as a photovoltaic cell, can be joined to the LCP layer using an adhesive, such as a solvent-based adhesive or a melt-adhesive. The adhesive can be extruded onto the LCP layer, co-extruded with the LCP layer, dispersion cast onto the LCP layer, or any combination thereof. In an embodiment, the adhesive can include an encapsulant.

Many different aspects and embodiments are possible. Some of those aspects and embodiments are described below. After reading this specification, skilled artisans will appreciate that those aspects and embodiments are only illustrative and do not limit the scope of the present invention.

In a first aspect, an optoelectronic structure can include an LCP layer having a first surface and a second surface opposite the first surface. The LCP layer can include a liquid crystal polymer. The optoelectronic structure can further include an optoelectronic device adjacent the first surface of the LCP layer. The liquid crystal polymer can be at least partially exposed to a gas at the second surface. In an embodiment, the optoelectronic device can be a photovoltaic cell. In another embodiment, the optoelectronic device can include an LED.

In an embodiment of the first aspect, the gas includes a hydrogen-containing or oxygen-containing gas, such as water vapor, diatomic oxygen, nitrogen oxides, carbon oxides, sulfur oxides, or any combination thereof. In a further embodiment, the liquid crystal polymer can be at least partially exposed to an outdoor environment. In another embodiment, the liquid crystal polymer can include a thermotropic liquid crystal polymer. In yet another embodiment, the liquid crystal polymer can include a biaxially oriented liquid crystal polymer. In a further embodiment, the liquid crystal polymer can have a dielectric breakdown voltage of at least about 23 kV/mm.

In a further embodiment of the first aspect, the LCP layer can have a thickness of at least about 2.5 microns. In an embodiment, the LCP layer can have a thickness of not greater than about 250 microns. In a further embodiment, the LCP layer can include a carbon filler, a glass fiber, a mineral, a nano-particle, or any combination thereof. In another embodiment, the LCP layer can include a desiccant. The desiccant can include an oxide, a chloride, a boric anhydride, a sulfate, a hydroxide, or any combination thereof.

In yet another embodiment of the first aspect, the LCP layer can further include at least one metal-containing sheet and at least one liquid crystal polymer film. In a particular embodiment, the at least one metal-containing sheet can include first and second metal-containing sheets. The first metal-containing sheet can include a first passageway, the second metal-containing sheet can include a second passageway, and the first and second passageways can be unaligned. In another particular embodiment, the at least one LCP film can include a first LCP film disposed between the first and second metal-containing sheets. The metal-containing sheet can include a foil or a metallized polymer film.

In a further embodiment of the first aspect, the optoelectronic structure can further include a polymer layer disposed between the LCP layer and the optoelectronic device. In an embodiment, the polymer layer can have a thickness of at least about 12 microns. Further, the polymer layer may have a thickness of not greater than about 750 microns. In a particular embodiment, the polymer layer can include an encapsulant, such as a polyethylene, a polypropylene, a polyamide, a ethylene propylene diene monomer, a polyester, a polycarbonate, an ethylene-propylene elastomer copolymers, a copolymer of ethylene or propylene with acrylic or methacrylic acid, an acrylate, a methacrylate, a ethylene-propylene copolymer, a poly alpha olefin melt adhesive, an ionomer, an acid functionalized polyolefin, a polyurethane, an olefin elastomer, an olefinic block copolymer, a thermoplastic silicone, an ethylene vinyl acetate (EVA), a polyvinyl butyral, a fluoropolymer, or any combination thereof. In another particular embodiment, the polymer layer can include a dielectric material. The dielectric material can include a polyethylene terephthalate, a polycarbonate, or any combination thereof. The polymer layer can further include a pigment, a UV stabilizer, an antioxidant, or any combination thereof.

In a second aspect, an optoelectronic structure can include an LCP layer and an optoelectronic device adjacent the LCP layer. The LCP film can include a thermotropic liquid crystal polymer. In an embodiment, the optoelectronic device can be a photovoltaic cell. In another embodiment, the optoelectronic device can include an LED.

In an embodiment of the second aspect, the LCP can be at least partially exposed to a gas, such as an outdoor environment. In yet another embodiment, the liquid crystal polymer can include a biaxially oriented LCP. In a further embodiment, the LCP can have a dielectric breakdown voltage of at least about 23 kV/mm.

In a further embodiment of the second aspect, the LCP layer can have a thickness of at least about 2.5 microns. In an embodiment, the LCP layer may have a thickness of not greater than about 250 microns. In a further embodiment, the LCP layer can include a carbon filler, a glass fiber, a mineral, a nano-particle, or any combination thereof. In another embodiment, the LCP layer can include a desiccant. The desiccant can include an oxide, a chloride, a boric anhydride, a sulfate, a hydroxide, or any combination thereof.

In yet another embodiment of the second aspect, the LCP layer can further include at least one metal-containing sheet and at least one LCP film. In a particular embodiment, the at least one metal-containing sheet can include first and second metal-containing sheets. The first metal-containing sheet can include a first passageway, the second metal-containing sheet can include a second passageway, and the first and second passageways can be unaligned. In another particular embodiment, the at least one LCP film can include a first LCP film disposed between the first and second metal-containing sheets. The metal-containing sheet can include a metal foil or a metallized polymer film.

In a further embodiment of the second aspect, the optoelectronic structure can further include a polymer layer disposed between the LCP layer and the optoelectronic device. In an embodiment, the polymer layer can have a thickness of at least about 12 microns. Further, the polymer layer may have a thickness of not greater than about 750 microns. In a particular embodiment, the polymer layer can include an encapsulant, such as a polyethylene, a polypropylene, a polyamide, a ethylene propylene diene monomer, a polyester, a polycarbonate, an ethylene-propylene elastomer copolymers, a copolymer of ethylene or propylene with acrylic or methacrylic acid, an acrylate, a methacrylate, a ethylene-propylene copolymer, a poly alpha olefin melt adhesive, an ionomer, an acid functionalized polyolefin, a polyurethane, an olefin elastomer, an olefinic block copolymer, a thermoplastic silicone, an ethylene vinyl acetate, a polyvinyl butyral, a fluoropolymer, or any combination thereof. In another particular embodiment, the polymer layer can include a dielectric material. The dielectric material can include a polyethylene terephthalate, a polycarbonate, or any combination thereof. The polymer layer can further include a pigment, a UV stabilizer, an antioxidant, or any combination thereof.

In a third aspect, an optoelectronic structure can include a LCP layer and an optoelectronic device adjacent to the LCP layer. The LCP layer can include a liquid crystal polymer and an additive to reduce the migration of a hydrogen-containing material through the polymer layer. In an embodiment, the optoelectronic device can be a photovoltaic cell. In another embodiment, the optoelectronic device can include an LED.

In an embodiment of the third aspect, the liquid crystal polymer can be at least partially exposed to a gas, such as an outdoor environment. In yet another embodiment, the liquid crystal polymer can include a biaxially oriented liquid crystal polymer. In a further embodiment, the liquid crystal polymer can have a dielectric breakdown voltage of at least about 23 kV/mm.

In a further embodiment of the third aspect, the LCP layer can have a thickness of at least about 2.5 microns. In an embodiment, the LCP layer may have a thickness of not greater than about 250 microns. In a further embodiment, the LCP layer can include a carbon filler, a glass fiber, a mineral, a nano-particle, or any combination thereof. In another embodiment, the LCP layer can include a desiccant. The desiccant can include an oxide, a chloride, a boric anhydride, a sulfate, a hydroxide, or any combination thereof.

In a further embodiment of the third aspect, the optoelectronic structure can further include a polymer layer disposed between the LCP layer and the optoelectronic device. In an embodiment, the polymer layer can have a thickness of at least about 12 microns. Further, the polymer layer may have a thickness of not greater than about 750 microns. In a particular embodiment, the polymer layer can include an encapsulant, such as a polyethylene, a polypropylene, a polyamide, a ethylene propylene diene monomer, a polyester, a polycarbonate, an ethylene-propylene elastomer copolymers, a copolymer of ethylene or propylene with acrylic or methacrylic acid, an acrylate, a methacrylate, a ethylene-propylene copolymer, a poly alpha olefin melt adhesive, an ionomer, an acid functionalized polyolefin, a polyurethane, an olefin elastomer, an olefinic block copolymer, a thermoplastic silicone, an ethylene vinyl acetate, a polyvinyl butyral, a fluoropolymer, or any combination thereof. In another particular embodiment, the polymer layer can include a dielectric material. The dielectric material can include a polyethylene terephthalate, a polycarbonate, or any combination thereof. The polymer layer can further include a pigment, a UV stabilizer, an antioxidant, or any combination thereof.

In a forth aspect, an optoelectronic structure can include a barrier layer and an optoelectronic device adjacent the barrier layer. The barrier layer can include at least one LCP film and at least one metal-containing sheet. The LCP film can include a liquid crystal polymer. In an embodiment, the optoelectronic device can be a photovoltaic cell. In another embodiment, the optoelectronic device can include an LED.

In an embodiment of the forth aspect, the liquid crystal polymer can be at least partially exposed to a gas. In another embodiment, the liquid crystal polymer can include a thermotropic liquid crystal polymer. In yet another embodiment, the liquid crystal polymer can include a biaxially oriented liquid crystal polymer. In a further embodiment, the liquid crystal polymer can have a dielectric breakdown voltage of at least about 23 kV/mm.

In a further embodiment of the forth aspect, the barrier layer can have a thickness of at least about 2.5 microns. In an embodiment, the barrier layer may have a thickness of not greater than about 250 microns. In a further embodiment, the barrier layer can include a carbon filler, a glass fiber, a mineral, a nano-particle, or any combination thereof.

In yet another embodiment of the forth aspect, the at least one metal-containing sheet can include first and second metal-containing sheets. The first metal-containing sheet can include a first passageway, the second metal-containing sheet can include a second passageway, and the first and second passageways can be unaligned. In another particular embodiment, the at least one liquid crystal polymer film can include a first liquid crystal polymer film disposed between the first and second metal-containing sheets. The metal-containing sheet can include a foil or a metallized polymer film.

In a further embodiment of the forth aspect, the optoelectronic structure can further include a polymer layer disposed between the barrier layer and the optoelectronic device. In an embodiment, the polymer layer can have a thickness of at least about 12 microns. Further, the polymer layer may have a thickness of not greater than about 750 microns. In a particular embodiment, the polymer layer can include an encapsulant, such as a polyethylene, a polypropylene, a polyamide, a ethylene propylene diene monomer, a polyester, a polycarbonate, an ethylene-propylene elastomer copolymers, a copolymer of ethylene or propylene with acrylic or methacrylic acid, an acrylate, a methacrylate, a ethylene-propylene copolymer, a poly alpha olefin melt adhesive, an ionomer, an acid functionalized polyolefin, a polyurethane, an olefin elastomer, an olefinic block copolymer, a thermoplastic silicone, an ethylene vinyl acetate, a polyvinyl butyral, a fluoropolymer, or any combination thereof. In another particular embodiment, the polymer layer can include a dielectric material. The dielectric material can include a polyethylene terephthalate, a polycarbonate, or any combination thereof. The polymer layer can further include a pigment, a UV stabilizer, an antioxidant, or any combination thereof.

In a fifth aspect, a method of forming an optoelectronic structure can include heating a thermotropic liquid crystal polymer to a temperature above a melting temperature of the liquid crystal polymer, forming a melt-processed film including the liquid crystal polymer, and joining an optoelectronic device and the melt-processed film. In an embodiment, the optoelectronic device can be a photovoltaic cell. In another embodiment, the optoelectronic device can include an LED.

In an embodiment of the fifth aspect, the temperature can be at least about 290° C. In another embodiment, the temperature may be not greater than about 400° C. In yet another embodiment, forming the melt-processed film can include extruding the liquid crystal polymer. In an alternate embodiment, forming the melt-processed film can include blowing the liquid crystal polymer.

In a further embodiment of the fifth aspect, the optoelectronic structure can further include a polymer layer disposed between the melt-processed film and the optoelectronic device. In an embodiment, the polymer layer can have a thickness of at least about 12 microns. Further, the polymer layer may have a thickness of not greater than about 750 microns. In a particular embodiment, the polymer layer can include an encapsulant, such as a polyethylene, a polypropylene, a polyamide, a ethylene propylene diene monomer, a polyester, a polycarbonate, an ethylene-propylene elastomer copolymers, a copolymer of ethylene or propylene with acrylic or methacrylic acid, an acrylate, a methacrylate, a ethylene-propylene copolymer, a poly alpha olefin melt adhesive, an ionomer, an acid functionalized polyolefin, a polyurethane, an olefin elastomer, an olefinic block copolymer, a thermoplastic silicone, an ethylene vinyl acetate (EVA), a polyvinyl butyral, a fluoropolymer, or any combination thereof. In another particular embodiment, the polymer layer can include a dielectric layer. The dielectric layer can include a polyethylene terephthalate, a polycarbonate, or any combination thereof. The polymer layer can further include a pigment, a UV stabilizer, an antioxidant, or any combination thereof. In an embodiment, after joining the optoelectronic device, the optoelectronic device can be closer to the polymer layer than the melt-processed film.

### EXAMPLES

Water Vapor Transmission Rate is measured using a Mocon, Inc. Permatran-W Model 3/31 Water Vapor Permeation Testing Instrument according to ASTM F1249, at a temperature of 38° C., and 100% relative humidity (RH).

Dielectric breakdown strength is measured according to ASTM D149 using Beckman Instruments, Inc. Model QC101A Dielectric Tester. Films are placed between circular electrodes having a diameter of 6.35 mm (0.25 inch). A ramped direct current (DC) voltage is applied at a constant ramp rate (500 V/s) starting from zero volts. The voltage at which a burn through of the film thickness is observed is reported as the dielectric breakdown voltage. Breakdown strength in V/mil is obtained by dividing Breakdown voltage by film thickness.

Partial Discharge is determined using the partial discharge method outlined in IEC 16730-2 using a Kikusui America, Inc. Model KPD2050 Partial Discharge Tester and circular electrodes measuring 50 mm and 30 mm. An alternating current (AC) voltage is applied, ramping up to the inception of partial discharge and 10% further, then ramping down to the extinction voltage—the level at which the charge intensity drops below 1 pC. The measurement is carried out at least 10 times. The maximum system voltage for the material is the average minus the standard deviation of the extinction voltage (AC peak), divided by 1.5.

### Example 1

A melt-processed LCP polymer film is laminated to both sides of a multilayer film using a solvent based polyurethane adhesive. The multilayer film includes LLDPE (50μ)/Metallized PET (12μ)/Al foil (6μ)/biaxially-oriented polypropylene (BOPP) (50μ)(V11840P, commercially available from Hanita Coatings RCA Ltd.) One hundred parts of polyurethane adhesive (Bostik EPS 877) are mixed with nine parts of catalyst (Boscodur 16221). The mixture is placed on mixing rolls for about 20 minutes until a clear solution is obtained. The resultant adhesive is applied to a corona treated LCP film. For a 12.7 micron (0.5 mil) dry thickness, approximately a 76.2 microns (3 mil) gap setting is used on hand drawdown equipment. The adhesive is dried to at least partially remove the solvent by exposing the adhesive to 100° C. for 2 min. The multilayer film is placed on the dried adhesive coating on the LCP film. A squeegee is used to press the multilayer film against the LCP layer and smooth out any wrinkles The 2-layer construction is passed through a ChemInstruments, Inc. Model HL-100 hot roll laminator with a nip pressure dial setting of 40 psi and rolls heated to 120° C. (250° F.). An additional layer of LCP is applied to the multilayer film opposite the first LCP film by applying adhesive to the additional LCP film and laminating as described above with respect to the first LCP film. Adhesion strength of the laminates is tested by attempting to separate by hand.

### Example 2

A melt-processed LCP film is laminated to one side of a second multilayer film using a thermal bonding adhesive. The multilayer film includes LLDPE (50μ)/Metallized PET (12μ)/Al foil (6μ)/BOPP (50μ) (V11840P, commercially available from Hanita Coatings RCA Ltd.) The adhesion used is a thermoplastic bonding film (3M™ Therm-Bond Film 668 commercially available from 3M). The bonding film is removed from the release coated paper liner and placed between the two films to be laminated (LCP and multilayer film). The films are pressed through ChemInstruments, Inc. Model HL-100 hot roll laminator with a nip pressure dial setting of 40 psi and rolls heated to 135° C. (275° F.). Adhesion strength of this laminates is judged to be acceptable when attempting to separate by hand. The thickness, breakdown voltage, breakdown strength, partial discharge, and Water Vapor Transition Rate are shown in Table 1.

TABLE 1

| | | Breakdown | Breakdown | Partial | |
|---|---|---|---|---|---|
| | Thickness | voltage | strength | Discharge | WVTR |
| | (microns) | (kV) | (kV/mm) | (Vmax) | (g/m²/d) |
| Example 2 | 406 | 35 | 84.6 | 1123 | <0.01 |

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

1. An optoelectronic structure comprising:
a liquid crystal polymer layer including a liquid crystal polymer, the liquid crystal polymer layer including a first surface and a second surface opposite the first surface; and
an optoelectronic device adjacent the first surface of the liquid crystal polymer layer,
wherein the liquid crystal polymer is at least partially exposed to a hydrogen-containing or oxygen-containing gas at the second surface.

2. The optoelectronic structure of claim 1, wherein optoelectronic device is a photovoltaic cell.

3.-6. (canceled)

7. The optoelectronic structure of claim 1, wherein the liquid crystal polymer includes a biaxially oriented liquid crystal polymer.

8. The optoelectronic structure of claim 1, wherein the liquid crystal polymer has a dielectric breakdown voltage of at least about 23 kV/mm.

9. The optoelectronic structure of claim 1, wherein the liquid crystal polymer layer includes a desiccant.

10. The optoelectronic structure of claim 9, wherein the desiccant includes an oxide, a chloride, a boric anhydride, a sulfate, a hydroxide, or any combination thereof.

11. The optoelectronic structure of claim 1, wherein the liquid crystal polymer layer further includes at least one metal-containing sheet and at least one liquid crystal polymer film.

12. The optoelectronic structure of claim 11, wherein the at least one metal-containing sheet includes first and second metal-containing sheets.

13. The optoelectronic structure of claim 12, wherein the first metal-containing sheet includes a first passageway, the second metal-containing sheet includes a second passageway, and the first and second passageways are not aligned.

14. The optoelectronic structure of claim 12, wherein the at least one liquid crystal polymer film includes a first liquid crystal polymer film disposed between the first and second metal-containing sheets.

15. The optoelectronic structure of claim 11, wherein the metal-containing sheet includes a foil.

16. The optoelectronic structure of claim 11, wherein the metal-containing sheet includes a metallized polymer film.

17. The optoelectronic structure of claim 1, wherein the liquid crystal polymer layer has a thickness of at least about 2.5 microns and not greater than about 250 microns.

18. (canceled)

19. The optoelectronic structure of claim 1, further comprising a polymer layer between the liquid crystal polymer layer and the optoelectronic device.

20. The optoelectronic structure of claim 19, wherein the polymer layer includes an encapsulant.

21. (canceled)

22. The optoelectronic structure of claim 19, wherein the polymer layer includes a dielectric material.

23. (canceled)

24. The optoelectronic structure of claim 19, wherein the polymer layer has a thickness of at least about 12 microns and not greater than about 750 microns.

25. (canceled)

26. An optoelectronic structure comprising:
a liquid crystal polymer layer including a thermotropic liquid crystal polymer; and
an optoelectronic device adjacent to the liquid crystal polymer layer.

27.-90. (canceled)

91. A method of forming an optoelectronic structure comprising:
heating a liquid crystal polymer to a temperature above a melting temperature of the liquid crystal polymer;
forming a melt-processed film including the liquid crystal polymer; and
joining an optoelectronic device and the melt-processed film.

92.-94. (canceled)

95. The method of claim 91, wherein the temperature is at least about 290° C.

96. The method of claim 91, wherein the temperature is not greater than about 400° C.

97. The method of claim 91, wherein forming the melt-processed film includes extruding the liquid crystal polymer.

98. (canceled)

99. The method of claim 91, further comprising joining the melt-processed film with a polymer layer prior to joining the optoelectronic device.

100.-104. (canceled)
